(19) United States
(12) Patent Application Publication
(10) Pub. No.: US 2007/0007984 A1
(43) Pub. Date: Jan. 11, 2007

(54) Socket for inspection apparatus

(75) Inventors: Yutaka Kojima, Kanagawa (JP); Hiroyuki Hama, Tokyo (JP); Shintaro Takaki, Tokyo (JP); Shin Sakiyama, Tokyo (JP)

Correspondence Address: OSHA LIANG L.L.P., 1221 MCKINNEY STREET, SUITE 2800, HOUSTON, TX, 77010, US

(73) Assignees: Molex Japan Co., Ltd., Yamato-shi (JP); Advantest Corporation, Tokyo (JP)

(21) Appl. No.: 11/481,586

(22) Filed: Jul. 6, 2006

(30) Foreign Application Priority Data
Jul. 6, 2005 (JP) 2005-197812

(51) Int. Cl. G01R 31/26

(52) U.S. Cl. 324/765

(57) ABSTRACT

A socket for an inspection apparatus for connecting an inspection circuit board and an inspected device includes: a plate-like housing including a first surface opposed to a surface on which a terminal of the inspected device is disposed and a second surface opposed to a surface on which an electrode of the inspection circuit board is disposed, the housing having a terminal-receiving holes which extends through the housing in the thickness direction thereof; and a connection terminal attached to the housing for electrically conducting the terminal of the inspected device and the electrode of the inspection circuit board, the connection terminal including a elastically deformable one-piece member which is a bent elongated member and being held in the terminal-receiving hole in the housing so as to be movable in the thickness direction of the housing.

### CROSS REFERENCE TO RELATED APPLICATION

The present application relates to and claims priority from a Japanese Patent Application No.2005-197812 filed in Japan on Jul. 6th, 2005, the contents of which are incorporated herein by reference for all purpose.

### BACKGROUND OF THE INVENTION

1. Field of the Invention

The present invention relates to a socket for an inspection apparatus.

2. Description of the Related Art

Typically, products of a semiconductor device, such as an IC or LSI (large scale integrated circuits), which have been packaged in an assembly step, are inspected for electrical characteristics, and only products which have been assured to have no failure are shipped. In a semiconductor inspection apparatus for inspecting the electrical characteristics of semiconductor devices, terminals of a packaged semiconductor device product are connected to an inspection circuit board having an inspection circuit, via a socket for the semiconductor inspection apparatus, as disclosed, for example, in Japanese Patent Application Publication No. 2003-84047).

FIG. 7 is a cross sectional view of a conventional socket for an inspection apparatus.

In FIG. 7, reference numeral 301 shows a socket for a semiconductor inspection apparatus. The socket electrically connects terminals 302a of a packaged semiconductor device 302 to respective electrodes 303a of an inspection circuit board 303 connected to an unillustrated semiconductor inspection apparatus, whereby the semiconductor device 302 is inspected for electrical characteristics.

The semiconductor socket for an inspection apparatus 301 includes a housing 311 of an insulative material such as resin, the housing having a plurality of insertion holes which are located at predetermined intervals to correspond to the terminals 302a of the semiconductor device 302. A probe is accommodated in each of the insertion holes. The probe, which is generally called a “pogopin” or “spring probe”, has a guide tube 312 formed of a conductive material, and first and second probe pins 315 and 316 which are formed of a conductive material and which are inserted into the guide tube 312 from the lower and upper ends thereof, respectively. An unillustrated spring is disposed within the guide tube 312 to be interposed between the first and second probe pins 315 and 316. Since the spring can expand and contract, the distance between the first and second probe pins 315 and 316 can be changed, and, therefore, the entire probe can expand and contract. Thus, even when the lower surface of the semiconductor device 302 or the upper surface of the inspection circuit board 303 has a distortion, the probe can absorb the distortion through expansion or contraction to thereby electrically connect the terminal 302a of the semiconductor device 302 and the electrode 303a of the inspection circuit board 303 to each other.

The semiconductor socket for an inspection apparatus 301 includes a conductive sheet 317 disposed between the first probe pins 315 and the inspection circuit board 303. The conductive sheet 317 includes: an elastic sheet 317a which is formed of a resin and which has a number of small conductive balls embedded therein; first electrodes 317b which are formed on one surface of the elastic sheet 317a and which are to come into contact with the respective first probe pins 315; and second electrodes 317c which are formed on the other surface of the elastic sheet 317a and which are to come into contact with the respective electrodes 303a of the inspection circuit board 303.

However, in the conventional semiconductor socket for an inspection apparatus 301, since each probe is composed of a guide tube 312, first and second probe pins 315 and 316, and a spring, the structure of the probe is complex, resulting in high production cost. Moreover, since the probe has a structure in which a spring is disposed between the first and second probe pins 315 and 316, the length of the probe is not less than 3 to 5 mm, and the electrical passage thus becomes long, deteriorating electrical characteristics, including impedance, of the probe. In addition, since tip ends of the second probe pins 316 that come into contact with the respective terminals 302a of the semiconductor device 302 are sharp, the terminals 302a may be damaged.

### SUMMARY OF THE INVENTION

An object of the present invention is to solve the above-mentioned problem in the conventional socket for an inspection apparatus and to provide a reliable socket for an inspection apparatus which includes connection terminals, each being formed through bending of an elongated member so as to be elastically deformable, the connection terminals being held in respective terminal-receiving holes, which extend through a plate-like housing, so as to be movable in the vertical direction. The socket for an inspection apparatus can absorb a deformation of an inspected device, the housing, or an inspection circuit board; has a simple structure which enables reduction of cost; has a reduced electrical passage length which improves electrical characteristics of the socket; and does not damage the terminals of the inspected device.

To achieve the above object, the socket for an inspection apparatus includes: a plate-like housing and connection terminals attached to the housing; a first main surface of the housing facing a surface of an inspected device that includes terminals disposed on the surface; a second main surface of the housing facing a surface of an inspection circuit board that includes electrodes disposed on the surface; the connection terminals electrically connecting the terminals of the inspected device and the electrodes of the inspection circuit board. The housing includes terminal-receiving holes which extend through the housing in the thickness direction thereof for receiving the connection terminals. Each of the connection terminals is an elastically deformable one-piece member which is formed through bending of an elongated member, and is held in the corresponding terminal-receiving hole so as to be movable in the thickness direction of the housing.

Preferably, each of the terminal-receiving holes includes an inspected-object-terminal-receiving portion which is formed on the first main surface of the housing for receiving the corresponding terminal of the inspected device.

Preferably, the terminals of the inspected device are solder balls, and the inspected-object-terminal-receiving portions each assume the form of a cone whose diameter decreases toward a direction away from the first main surface of the housing.

Preferably, each of the connection terminals has a generally S-shape, and includes an inspected object-side contact portion which is located near the first main surface of the housing and which comes into contact with the corresponding terminal of the inspected device, and an inspection-circuit-side contact portion which is located on the second main surface of the housing and which comes into contact with the corresponding electrode of the inspection circuit board.

Preferably, each of the terminal-receiving holes includes a projecting wall which projects in a direction perpendicular to the thickness direction of the housing; each of the connection terminals includes a projecting portion which projects in a direction opposite the projecting direction of the projecting wall; and the projecting portion engages with the projecting wall to thereby prevent the connection terminal from coming off the terminal-receiving hole.

The socket for an inspection apparatus according to the present invention includes connection terminals, each being formed through bending of an elongated member so as to be elastically deformable, the connection terminals being held in respective terminal-receiving holes, which extend through a plate-like housing, so as to be movable in the vertical direction. The socket for an inspection apparatus can absorb a deformation of an inspected device, the housing, or an inspection circuit board; has a simple structure which enables reduction of cost; has a reduced electrical passage length which improves electrical characteristics of the socket; and does not damage the terminals of the inspected device, enhancing the reliability of the socket for an inspection apparatus.

### BRIEF DESCRIPTION OF THE DRAWINGS

FIGS. 1A to 1C are perspective views of an socket for an inspection apparatus according to an embodiment of the present invention, showing a state of use of the socket;

FIGS. 2A and 2B are partial cross sectional views of the socket for an inspection apparatus according to the embodiment, showing the state of use thereof;

FIGS. 3A to 3D are view showing the structure of the socket for an inspection apparatus according to the embodiment;

FIGS. 4A to 4D are views relating to the embodiment and showing the structure of a terminal-receiving hole which receives a connection terminal;

FIGS. 5A to 5D are cross sectional views according to the embodiment and showing operation of mounting a device to be inspected to an inspection circuit board via the socket for an inspection apparatus;

FIGS. 6A to 6E are cross sectional views according to the embodiment and showing operation of mounting a connection terminal to a housing of the socket for an inspection apparatus; and

FIG. 7 is a cross sectional view of a conventional socket for an inspection apparatus.

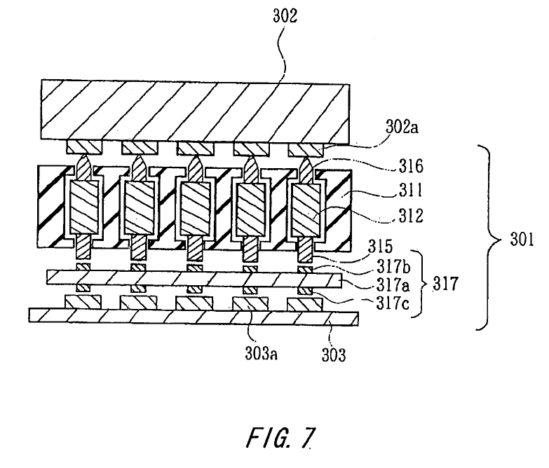

### DESCRIPTION OF THE PREFERRED EMBODIMENT

An embodiment of the present invention will next be described in detail with reference to the drawings.

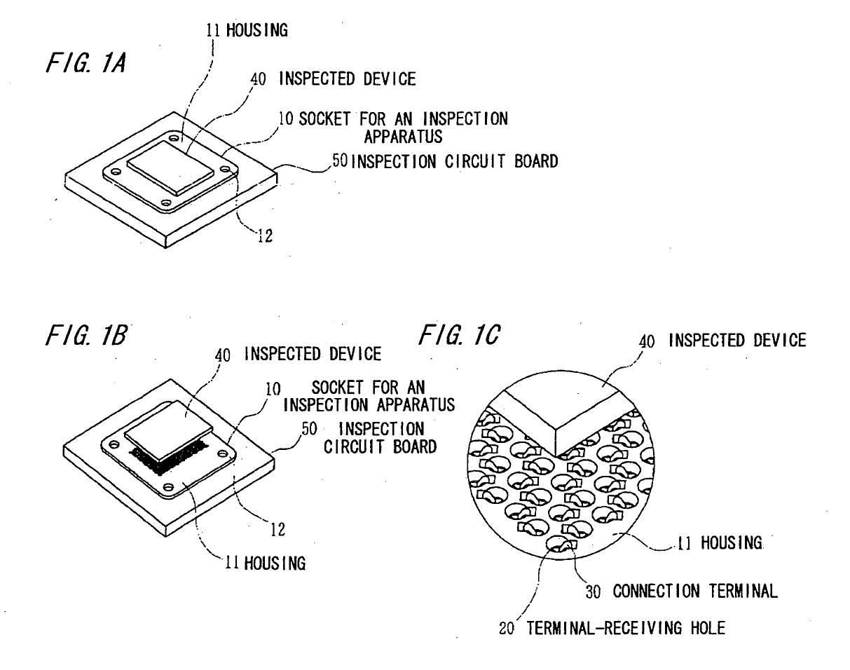

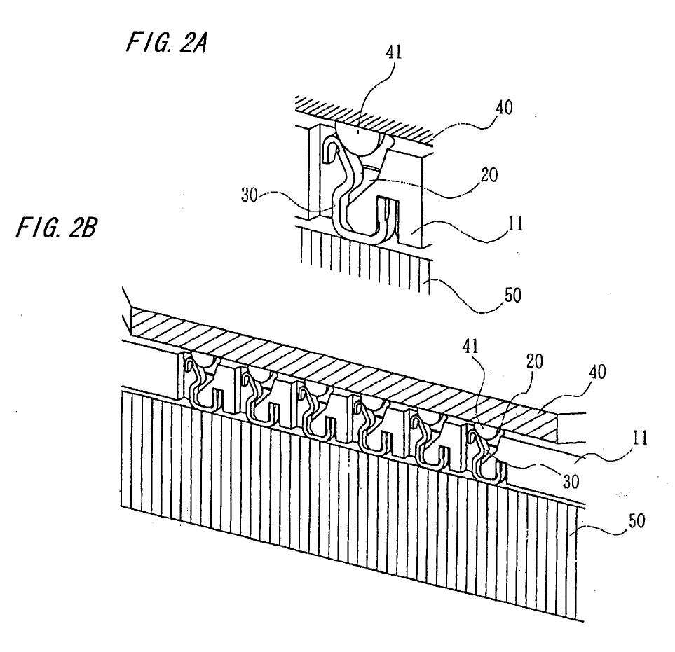

FIGS. 1A to 1C are perspective views of an socket for an inspection apparatus according to an embodiment of the present invention, showing a state of use of the socket; and FIGS. 2A and 2B are partial cross sectional views of the socket for an inspection apparatus according to the embodiment, showing the state of use thereof. Specifically, FIG. 1A shows a state in which a device to be inspected (hereinafter referred to as “inspected device”) is connected to an inspection circuit board via an socket for an inspection apparatus; FIG. 1B shows a state in which the inspected device is separated from the socket for an inspection apparatus for illustration; and FIG. 1C is a partial enlarged view of FIG. 1B. FIG. 2B is a cross sectional view showing a state in which the inspected device is connected to the inspection circuit board via the socket for an inspection apparatus; and FIG. 2A is a partial enlarged view of FIG. 2B.

In FIGS. 1A to 1C, reference numeral 10 denotes an socket for an inspection apparatus according to the embodiment of the present invention. The socket for an inspection apparatus has a plate-like housing (base plate) 11, which has a generally square or rectangular planar shape. The housing 11 has mounting holes 12 allowing unillustrated mounting members, such as bolts, to pass therethrough. The housing 11 is mounted to an inspection circuit board 50 such that a first main surface of the housing 11 faces the surface of an inspected device that includes terminals disposed thereon and that a second main surface of the housing 11 faces the surface of the inspection circuit board 50 that includes electrodes disposed thereon. The socket for an inspection apparatus 10 is used for inspection of electrical characteristics of the inspected device 40. The inspected device 40, which is a semiconductor device such as an IC or LSI, may be any type of electrical or electronic device, so long as the inspected device 40 has terminals disposed on one surface thereof. The terminals may be those having any form, including solder balls, flat plate electrode pads, elongated plate leads, and needle-shaped electrode pins. In the present embodiment, the inspected device 40 is a semiconductor device including a plurality of solder balls 41 on the reverse surface thereof as terminals.

The inspection circuit board 50 is connected to an unillustrated semiconductor inspection apparatus and mounted to, for example, an inspection table. The housing 11 may be mounted directly to the inspection circuit board 50, or may be mounted thereto via a mounting means, such as a mounting frame. The mounting holes 12 may be omitted as desired.

In the description of the present embodiment, terms for expressing direction, such as up, down, left, right, front, and rear, are for explaining the structure and action of portions of the socket for an inspection apparatus 10. However, these terms represent respective directions for the case where the socket for an inspection apparatus 10 is used in an orientation shown in the drawings, and must be construed to represent corresponding different directions when the orientation of the socket for an inspection apparatus 10 is changed.

The housing 11 is integrally formed of an insulative material such as synthetic resin, and includes a plurality of terminal-receiving holes 20 which extends through the housing 11 in the thickness direction; i.e., from the top surface to the reverse surface, as shown in FIGS. 2A and 2B. The terminal-receiving holes 20 receive connection terminals 30 which are formed of a conductive material such as metal. The terminal-receiving holes 20 and the connection terminals 30 are located such as to correspond to the respective solder balls (terminals) 41 of the inspected device 40. In the illustrated embodiment, the solder balls 41 are arranged in a grid pattern at a pitch of about 1 mm, similar to an ordinary semiconductor device, and the terminal-receiving holes 20 and the connection terminals 30 are also arranged to form in a grid pattern at a similar pitch.

Each of the connection terminals 30 is a generally S-shaped one-piece member integrally formed to be elastically deformable, through bending of an elongated member of a resilient material such as a metal plate. Since the connection terminals 30 have a simple structure, the vertical length of the terminals 30 in FIGS. 2A and 2B can be about one third of that of so-called pogopins or spring probes. When the inspected device 40 is connected to the inspection circuit board 50 via the socket for an inspection apparatus 10, as shown in FIGS. 2A and 2B, the connection terminals 30 come into contact with the solder balls 41 of the inspected device 40 and unillustrated electrode pads, serving as electrodes, formed on the top surface of the inspection circuit board 50, to thereby electrically connect the solder balls 41 of the inspected device 40 with the electrode pads formed on the top surface of the inspection circuit board 50.

Next, the structures of the terminal-receiving holes 20 and the connection terminals 30 will be described in detail.

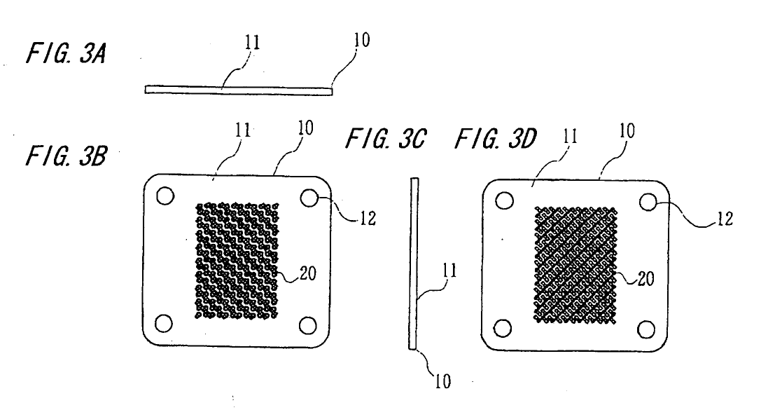

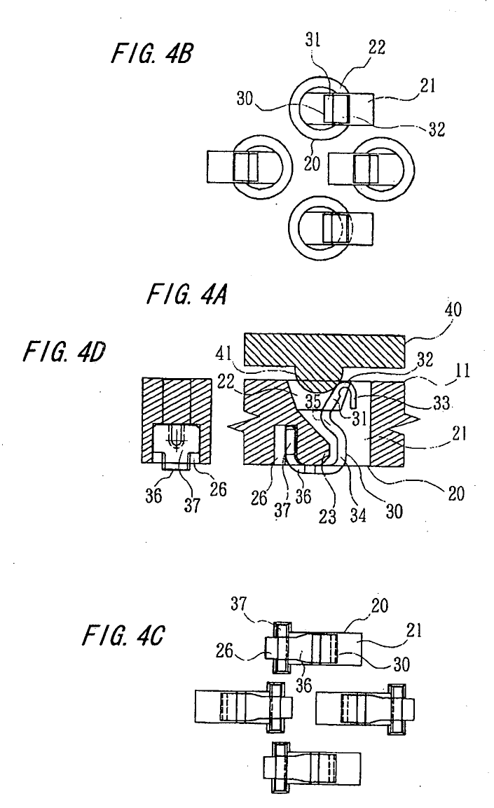

FIGS. 3A to 3D are view showing the structure of the socket for an inspection apparatus according to the embodiment; and FIGS. 4A to 4D are views relating to the embodiment and showing the structure of a terminal-receiving hole which receives a connection terminal. Specifically, FIG. 3A is a top view, FIG. 3B is a front elevation, FIG. 3C is a side elevation, and FIG. 3D is a bottom view. FIG. 4A is a sectional side view, FIG. 4B is a top view, FIG. 4C is a bottom view, and FIG. 4D is another sectional side view different form FIG. 4A.

As shown in FIGS. 3A to 3D, the terminal-receiving holes 20 are arranged in a grid pattern within a central region of the housing 11. In the illustrated example, the region, within which the terminal-receiving holes 20 are arranged, assumes a rectangular shape, but the region may assume any shape. The housing 11 has a marginal area that surrounds the region including the terminal-receiving holes 20, and a mounting frame or a similar member for mounting the hosing 11 to the inspection circuit board 50 may be attached to the housing 11 in the marginal area. The marginal area may assume any shape and may be of any size.

FIGS. 4A to 4D are enlarged views of some of the terminal-receiving holes 20 each receiving a connection terminal 30. FIGS. 4B and 4D are enlarged top and bottom views, respectively, of the housing 11, and show that the terminal-receiving holes 20 are located at nodes of a generally square grid pattern. Each of the terminal-receiving holes 20 includes a through-hole portion 21 extending through the housing 11 from the top surface to the bottom surface thereof, an inspected-object-terminal-receiving portion 22 formed adjacent to the upper surface of the housing 11, and an auxiliary hole 26 formed to be adjacent to the lower surface of the housing 11.

The through-hole portion 21 has a generally rectangular cross section of a width which is larger than that of the connection terminal 30. A projecting wall 23 which projects toward the center axis of the through-hole portion 21 is formed at the lower end of the through-hole portion 21; i.e., on the side wall of the through-hole portion 21 to be located adjacent to the lower surface of the housing 11.

In the present embodiment, each of the inspected-object-terminal-receiving portions 22 assumes the form of an inverted cone whose diameter decreases toward the lower side to receive a solder ball (terminal) 41 of the inspected device 40, and is connected to an upper part of the through-hole portion 21. The inspected-object-terminal-receiving portion 22 is located generally above the projecting wall 23. The diameter of the inspected-object-terminal-receiving portion 22 as measured at the top end thereof; i.e., at the upper surface of the housing 11, is larger than the maximum diameter of the solder ball 41.

The auxiliary hole 26 is a blind recess having a generally T-shaped cross section. The center axis of the auxiliary hole 26 is separated from the center axis of the through-hole portion 21. A lower end tail portion 37 of the connection terminal 30 is inserted into the auxiliary hole 26.

In the illustrated embodiment, the connection terminal 30 is integrally formed from an elongated plate member through bending along the longitudinal direction so as to form a generally S-shape. The connection terminal 30 includes an inspected-object-side contact portion 31 which extends obliquely; an upper tail portion 33 which is connected to the inspected-object-side contact portion 31 via an upper curved portion 32 and whose distal end is directed downward, the upper curved portion 32 having an arcuate outer surface; a body portion 34 which extends in the vertical direction; a projecting portion 35 which connects the inspected-object-side contact portion 31 and the body portion 34 to each other and which projects in a direction which is opposite the projecting direction of the projecting wall 23 of the terminal-receiving hole 20: an inspection-circuit-side contact portion 36 which is connected to the lower end of the body portion 34 and which extends in the lateral direction; and a lower end tail portion 37 which is connected to the inspection-circuit-side contact portion 36 and whose tip end is directed upward.

The body portion 34, the projecting portion 35, the inspected-object-side contact portion 31, the upper curved portion 32, and the upper tail portion 33 each have a width smaller than that of the through-hole portion 21 of the terminal-receiving portion 20, and are received in the through-hole portion 21. The inspected-object-side contact portion 31 and the upper curved portion 32 at least partially project into the inspected-object-terminal-receiving portion 22.

The lower, tail portion 37 has a wide portion which is wider than the remaining portions of the connection terminal 30 and which is inserted into and received in the auxiliary hole 26. The opposite ends of the wide portion are not nipped by the opposite inner walls of the auxiliary hole 26. Thus, the lower tail portion 37 is gently held by the auxiliary hole 26 so as to be movable vertically.

The inspection-circuit-side contact portion 36 is exposed from the lower end of the terminal-receiving hole 20 and slightly projects from the lower surface of the housing 11. The upper surface of the inspection-circuit-side contact portion 36 is located generally coplanar with the lower surface of the housing 11.

FIGS. 4A to 4D show the initial state after the connection terminal 30 has been placed in the terminal-receiving hole 20 of the housing 11 with the lower tail portion 37 being inserted into the auxiliary hole 26 with play such that the connection terminal 30 is movable in the vertical direction. However, actually, in the initial state, the connection terminal 30 is located lower than the position shown in FIGS. 4A to 4D, and the projecting portion 35 of the connection terminal 30 is in contact with the projecting wall 23 of the terminal-receiving hole 20. However, the present embodiment will be described under the assumption that, in the initial state, the upper end of the connection terminal 30; i.e., the upper end surface of the upper curved portion 32, is located generally coplanar with the upper surface of the housing 11.

Next, operation of connecting the inspected device 40 to the inspection circuit board 50 via the socket for an inspection apparatus 10 will be described.

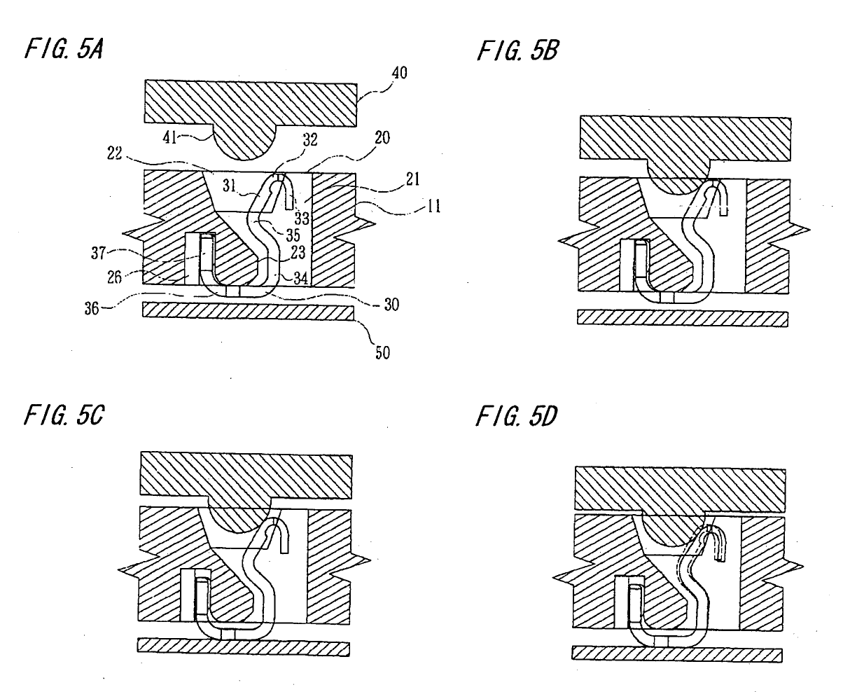

FIGS. 5A to 5D are cross sectional views relating to the embodiment and showing operation of mounting a device to be inspected to an inspection circuit board via the socket for an inspection apparatus. FIGS. 5A to 5D show the progress of the operation.

The socket for an inspection apparatus 10 is assumed to have previously been mounted on the inspection circuit board 50. In FIGS. 5A to 5D, there are not shown electrode pads which are formed on the upper surface of the inspection circuit board 50 and which are connected to conductive traces of the inspection circuit board 50. Since the electrode pads are disposed such as to correspond to the solder balls (electrode terminals) 41 of the inspected device 40, the electrode pads correspond to the terminal-receiving holes 20 and the connection terminals 30 of the socket for an inspection apparatus 10. The operation of connecting the inspected device 40 to the inspection circuit board 50 will be described under the assumption that the electrode pads are provided on the upper surface of the inspection circuit board 50 such as to face at least the inspection-circuit-side contact portions 36 of the connection terminals 30, and that the upper surface of the electrode pads are located coplanar with the upper surface of the inspection circuit board 50.

Here, description will be made under the assumption that, in the initial state after the socket for an inspection apparatus 10 has been mounted to the inspection circuit board 50, as shown in FIG. 5A, a gap is present between the lower surfaces of the inspection-circuit-side contact portions 36 of the connection terminals 30 and the upper surfaces of the electrode pads of the inspection circuit board 50, due to deformation of the housing 11 or the inspection circuit board 50, and the inspection-circuit-side contact portions 36 are not in contact with the electrode pads of the inspection circuit board 50. In the present embodiment, when the housing 11 of the socket for an inspection apparatus 10 and the inspection circuit board 50 have no deformation or distortion, and the lower surface of the housing 11 is parallel to the upper surface of the inspection circuit board 50, the inspection-circuit-side contact portions 36 and electrode pads of the inspection circuit board 50 are brought into contact with each other, and no gap is present between the lower surfaces of the inspection-circuit-side contact portions 36 and the upper surfaces of the electrode pads, in the initial state. However, here, as described above, description will be made under the assumption that a gap is present between the lower surfaces of the inspection-circuit-side contact portions 36 of the connection terminals 30 and the upper surfaces of the electrode pads of the inspection circuit board 50—i.e., the inspection-circuit-side contact portions 36 are not in contact with the electrode pads of the inspection circuit board 50—in order to demonstrate that, even when the housing 11 or the inspection circuit board 50 has a deformation or distortion, the socket for an inspection apparatus 10 can absorb the deformation or distortion.

In the present embodiment, in the initial state after the socket for an inspection apparatus 10 has been mounted to the inspection circuit board 50, the inspection-circuit-side contact portions 36 and the electrode pads of the inspection circuit board 50 are not connected together through any connection means such as soldering. This construction enables the socket for an inspection apparatus 10 to absorb the above-mentioned deformation or distortion, and ensures contact between the inspection-circuit-side contact portions 36 and the electrode pads of the inspection circuit board 50, even when the housing 11 or the inspection circuit board 50 has any deformed portion.

Subsequently, as shown in FIG. 5A, the inspected device 40 and the inspection circuit board 50 carrying the socket for an inspection apparatus 10 are moved relatively to each other, so that the lower surface of the inspected device 40 faces the upper surface of the housing 11. In this state, the lower surface of the inspected device 40 and the upper surface of the housing 11 are parallel to each other, and the solder balls 41 located on the lower surface of the inspected device 40 and the inspected-object-terminal-receiving portions 22 of the housing 11 are generally aligned.

In the state shown in FIG. 5A, a large gap is formed between the lower surface of the housing 11 and the upper surface of the inspection circuit board 50 due to deformation or distortion of the housing 11 or the inspected circuit board 50, as described above. Each of the connection terminals 30 is mounted to the housing 11 through engagement of the lower tail portion 37 with the auxiliary hole 26. Therefore, the upper surface of the inspection-circuit-side contact portion 36 is located generally coplanar with the lower surface of the housing 11, and the lower surface of the inspection-circuit-side contact portion 36 is separated from the corresponding electrode pad of the inspection circuit board 50.

Thereafter, the inspected device 40 and/or the inspection circuit board 50 are moved toward each other, so that, as shown in FIG. 5B, the solder balls 41 on the lower surface of the inspected device 40 enter the inspected-object-terminal-receiving portions 22 of the housing 11. In this case, the inspected-object-terminal-receiving portions 22 each have the shape of an inverted cone whose diameter decreases toward the lower side. Therefore, self alignment takes place, when the solder balls 41 are inserted into and engaged with the respective inspected-object-terminal-receiving portions 22.

Specifically, even when the solder balls 41 are inserted into the respective inspected-object-terminal-receiving portions 22 with the vertical center axes of the solder balls 41 being misaligned with the vertical center axes of the inspected-object-terminal-receiving portions 22, the vertical center axes of the solder balls 41 are automatically aligned with the vertical center axes of the inspected-object-terminal-receiving portions 22 by means of interaction between the hemispherical outer surfaces of the solder balls 41 and the conical wall surfaces of the inspected-object-terminal-receiving portions 22. Therefore, even when the inspected device 40 and the inspection circuit board 50 are not completely aligned in the horizontal or lateral direction, all the solder balls 41 fit into the respective inspected-object-terminal-receiving portions 22 through the above-described self-alignment effect, ensuring connection of the inspected device 40 to the inspection circuit board 50 via the socket for an inspection apparatus 10.

Subsequently, the inspected device 40 and/or the inspection circuit board 50 are further moved toward each other, so that, as shown in FIG. 5C, the solder balls 41 on the lower surface of the inspected device 40 enter more deeply in the respective inspected-object-terminal-receiving portions 22 of the housing 11. As a result, each of the solder balls 41 is brought into contact with the inspected-object-side contact portion 31 and/or the upper curved portion 32 of the connection terminal 30, to thereby apply a downward force to the connection terminal 30. In this case, the connection terminal 30 is mounted to the housing 11 through insertion of the lower tail portion 37 into the auxiliary hole 26, and the wide portion of the lower tail portion 37 and received and held in the auxiliary hole 26 with play. Therefore, by the downward force applied by the solder ball 41, the lower tail portion 37 is moved downward relative to the auxiliary hole 26. This causes the entire connection terminal 30 to move downward, and, as shown in FIG. 5C, the lower surface of the inspection-circuit-side contact portion 36 is brought into contact with the upper surface of the electrode pad of the inspection circuit board 50.

As mentioned above, the lower tail portions 37 are held in the respective auxiliary holes 26 with play to be movable in the vertical direction, so that the connection terminals 30 are movable relative to the housing 11. Therefore, even when a gap is formed between the lower surfaces of the inspection-circuit-side contact portions 36 of the connection terminals 30 and the upper surfaces of the electrode pads of the inspection circuit board 50 due to deformation or distortion of the housing 11 or the inspection circuit board 50, the lower surfaces of the inspection-circuit-side contact portions 36 and the upper surfaces of the electrode pads of the inspection circuit board 50 can be brought into contact with and electrically connected to each other, when the inspected device 40 is moved relative to the inspection circuit board 50 so as to move the solder balls 41 into the inspected-object-terminal-receiving portions 22 to thereby move the connection terminals 30 downward. That is, even when the housing 11 or the inspection circuit board 50 has a deformation or distortion, the socket for an inspection apparatus 10 can absorb the deformation or distortion, ensuring contact of the inspection-circuit-side contact portions 36 of the connection terminals 30 with the electrode pads of the inspection circuit board 50.

In addition, the inspected-object-side contact portions 31 of the contact terminals 30 extend obliquely (i.e., are inclined), and the upper curved portions 32 each have an arcuate outer surface. That is, the connection terminals 30 have no sharp portion which is directed upward. Therefore, when the solder balls 41 are brought into contact with the connection terminals 30, the solder balls 41 are not damaged.

Subsequently, the inspected device 40 and/or the inspection circuit board 50 are further moved toward each other, so that, as shown in FIG. 5D, the solder balls 41 formed on the lower surface of the inspected device 40 enter more deeply in the respective inspected-object-terminal-receiving portions 22 of the housing 11. Each of the solder balls 41 which have been brought into contact with the inspected-object-side contact portion 31 of the connection terminal 30 applies a larger downward force to the connection terminal 30. In this case, the lower surface of the inspection-circuit-side contact portion 36 has already come into contact with the upper surface of the corresponding electrode pad of the inspection circuit board 50, and the connection terminal 30 is therefore not moved downward. Since the connection terminal 30 is formed of a resilient material, the body portion 34 and/or other portions of the connection terminal 30 elastically deform and absorb the downward force. The solder ball 41 moves along the inclined surface of the obliquely extending inspected-object-side contact portion 31, while rubbing the inclined surface. Therefore, wiping effect is obtained. That is, matter (e.g., foreign objects) adhering to the surface of the solder ball 41 or the inclined surface of the inspected-object-side contact portion 31 and hindering electrical connection is removed through wiping. This ensures electrical connection between the solder ball 41 and the inspected-object-side contact portion 31.

In addition, since the connection terminals 30 elastically deforms, and the inspected-object-side contact portions 31 come into contact with the solder balls 41, errors in the relative positions between the inspected-object-side contact portions 31 and the solder balls 41 can be absorbed. That is, even when errors arise in the relative positions between the inspected-object-side contact portions 31 and the solder balls 41, contact between the inspected-object-side contact portions 31 and the solder balls 41 is maintained. Therefore, even when the inspected device 40 or the housing 11 has a deformation or distortion, and the lower surface of the inspected device 40 and the upper surface of the housing 11 are not parallel to each other, the inspected-object-side contact portions 31 of the connection terminals 30 and the solder balls 41 can be brought into mutual contact without fail. That is, even when the inspected device 40 or the housing 11 has a deformation our distortion, the socket for an inspection apparatus 10 can absorb the deformation or distortion, ensuring reliable contact with the inspected-object-side contact portions 31 of the connection terminals 30 and the solder balls 41 of the inspected device 40.

In addition, since a larger downward force is applied to each of the connection terminals 30 by the respective solder ball 41, the lower surface of the inspection-circuit-side contact portion 36 is pressed more strongly to the upper surface of the corresponding electrode pad of the inspection circuit board 50. This ensures more reliable contact between the inspection-circuit-side contact portion 36 of the connection terminal 30 and the electrode pad of the inspection circuit board 50.

Next, operation of mounting the connection terminals 30 to the terminal-receiving holes 20 of the housing 11 will be described.

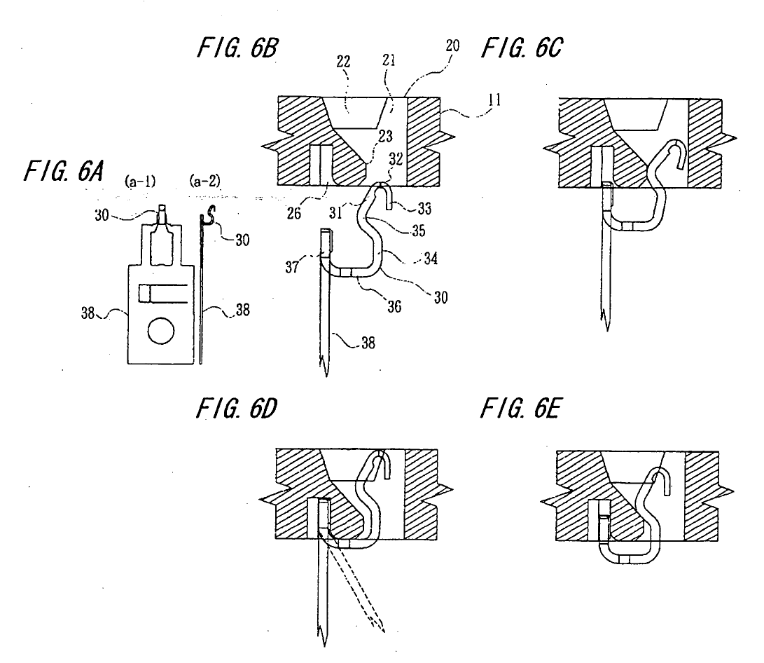

FIGS. 6A to 6E are cross sectional views relating to the embodiment and showing operation of mounting a connection terminal to a housing of the socket for an inspection apparatus. Specifically, Sections A-1 and A-2 of FIG. 6A show front and side views of the connection terminal before being mounted, respectively, and FIGS. 6B to 6E show the progress of the mounting operation.

The connection terminal 30 is formed of a plate of a conductive material such as metal through machining process, such as stamping and forming, such that the connection terminal 30 is formed integrally with a plate-like carrier portion 38 and that the connection terminal 30 is connected to the tip end of the carrier portion 38, as shown in FIG. 6A. In this case, the lower tail portion 37 of the connection terminal 30 is connected to the tip end of the carrier portion 38, and the body portion 34 and the lower tail portion 37 is parallel to the carrier portion 38.

As shown in FIG. 6B, the connection terminal 30 connected with the carrier portion 38 is located below the housing 11. The connection terminal 30 is positioned such that the lower tail portion 37 is aligned with the auxiliary hole 26, and that the vertical center axis of the lower tail portion 37 coincides with the vertical center axis of the auxiliary hole 26.

Subsequently, the carrier portion 38 is moved relatively toward the housing 11, so that, as shown in FIG. 6C, the inspected-object-side contact portion 31, the upper curved portion 32, and the upper tail portion 33 enter into the through-hole portion 21 from the lower end thereof, and that the tip end of the lower tail portion 37 enters the auxiliary hole 26. In this case, since the distance between the projecting portion 35 and the lower tail portion 37 is smaller than that between the side wall of the auxiliary hole 26 on the side toward the through-hole portion 21 and the distal end of the projecting wall 23, the projecting portion 35 comes into contact with the projecting wall 23, whereby the body portion 34 and/or other portions of the connection terminal 30 elastically deform, and the space between the projecting portion 35 and the lower tail portion 37 is expanded. Since the lower surface of the projecting portion 35 is inclined and connected to the inclined surface of the inspected-object-side contact portion 31, the space between the projecting portion 35 and the lower tail portion 37 is smoothly expanded.

Subsequently, the carrier portion 38 is further moved relatively toward the housing 11, so that the tail portion 37 is received in the auxiliary hole 26, and that the upper surface of the inspection-circuit-side contact portion 36 comes into contact with the lower surface of the housing 11, as shown in FIG. 6D. In this state, the lower tail portion 37 is engaged with the auxiliary hole 26, and the body portion 34, the projecting portion 35, the inspected-object-side contact portion 31, the upper curved portion 32, and the upper tail portion 33 are received in the through-hole portion 21. In other words, the connection terminal 30 is accommodated within the terminal-receiving hole 20 of the housing 11. Thereafter, the carrier portion 38 is bent as shown by the broken line in FIG. 6D, whereby the connecting portion between the lower tail portion 37 and the tip end of the carrier portion 38 is broken for separating the carrier portion 38 from the connection terminal 30. Thus, mounting of the connection terminal 30 to the terminal-receiving hole 20 is completed. As described above, the connection terminal 30 can be mounted to the housing 11 through a simple operation of moving the carrier portion 38 relatively toward the housing 11 while holding the carrier portion 38 and then bending the carrier portion 38. Therefore, the operation of mounting the connection terminal 30 to the housing 11 can be carried out automatically by use of a machine.

In some cases, when an external force such as vibration or shock is applied to the housing 11 to which the connection terminals 30 have been mounted, the connection terminals 30 may be moved downward, since the lower tail portion 37 of each of the connection terminals 30 is held in the auxiliary hole 26 with play so as to be movable in the vertical direction, and thus the connection terminal 30 is floatable. However, even in this case, the connection terminal 30 does not come off the terminal-receiving portion 20, since, as described above, the distance between the projecting portion 35 and the lower tail portion 37 is smaller than that between the inner side wall of the auxiliary hole 26 on the side toward the through-hole portion 21 and the distal end of the projecting wall 23, and the projecting portion 35 engages the projecting wall 23 as shown in FIG. 6E. Therefore, even when the socket for an inspection apparatus 10 is not handled carefully, the connection terminals 30 do not come off the housing 11. This feature facilitates handling of the socket for an inspection apparatus 10. In addition, when an operator manually applies to one of the connection terminal 30 a force sufficient to increase the distance between the projecting portion 35 and the lower tail portion 37 through elastic deformation of the body portion 34 and/or other portions of the connection terminal 30, the connection terminal 30 can be removed from the terminal-receiving hole 20. Therefore, any connection terminal 30 that has been damaged or has become dirty can be readily removed. Since any of the connection terminals 30 can be selectively replaced one by one, production yield of the socket for an inspection apparatus 10 can be enhanced.

In the present embodiment, the connection terminals 30 of the socket for an inspection apparatus 11 are each formed through bending of an elongated member, and thus are elastically deformable. The connection terminals 30 are held in the terminal-receiving holes 20, which extend through the housing 11, such as to be movable in the vertical direction: i.e., in a floatable condition. Therefore, even when the inspected device 40, the housing 11, or the inspection circuit board 50 has a deformation or distortion, the deformation or distortion can be absorbed.

Furthermore, the connection terminal 30 is formed through bending of an elongated member. That is, the connection terminal 30 is not a probe which include a plurality of components, including a spring and a guide tube, assembled together, such as pogopin, spring probe, or other conventional probes. The connection terminal 30 has a simple structure and a reduced vertical length. This structure decreases the production cost, and the shortened electrical passages improve the electrical characteristics such as impedance. In addition, since the socket for an inspection apparatus 10 has such a simple structure; i.e., can be produced by inserting the connection terminals 30 into the respective terminal-receiving holes 20 of the housing 11. This feature can reduce the cost required to assemble the socket for an inspection apparatus 10. Further, since the terminal-receiving holes 20 and the connection terminals 30 are simple in structure, the connection terminals 30 may be disposed at reduced intervals so as to increase the density of the connection terminals 30.

Even when the socket for an inspection apparatus 10 is mounted to the inspection circuit board 50, no connecting means, such as soldering is required so as to establish connection between the inspection-circuit-side contact portions 36 of the connection terminals 30 and the electrical pads of the inspection circuit board 50. Moreover, the socket for an inspection apparatus 10 has a single-layer structure composed of the housing 11. Therefore, the socket for an inspection apparatus 10 can readily be mounted to or removed from the inspection circuit board 50: i.e., the socket for an inspection apparatus 10 can be replaced easily.

The inspected-object-side contact portion 31 of each connection terminal 30 extends obliquely, and the upper curved portion 32 has an arcuate outer surface. Therefore, when the solder balls 41 of the inspected device 40 are not damaged, which damage would otherwise occur upon contact with the respective connection terminals 30. Since each of the solder balls 41 moves along the inclined surface of the inspected-object-side contact portion 31 while rubbing the inclined surface, wiping effect can be generated, which ensures reliable electrical connection between the solder ball 41 and the inspected-object-side contact portion 31. When the solder balls 41 are caused to enter and fit into the respective inspected-object-terminal-receiving portions 22, self alignment takes place. Therefore, even when the inspected device 40 and the inspection circuit board 50 are not aligned completely, the inspected device 40 can be connected to the inspection circuit board 50 via the socket for an inspection apparatus 10 without fail.

Since the connection terminals 30 can be selectively replaced one by one, production yield of the socket for an inspection apparatus 10 can be enhanced. The connection terminal 30 can be mounted to the housing 11 through a simple operation of moving the carrier portion 38 relatively toward the housing 11 while holding the carrier portion 38 and then bending the carrier portion 38. Therefore, the operation of attaching the connection terminals 30 to the housing 11 can be performed automatically by use of a machine. The socket for an inspection apparatus 10 can easily cope with changes in the external shape of the housing 11 and in the number and arrangement of the connection terminals 30.

The present invention is not limited to the above-described embodiments. Numerous modifications and variations of the present invention are possible in light of the spirit of the present invention, and they are not excluded from the scope of the present invention.

What is claimed is:

1. A socket for an inspection apparatus (10) for connecting an inspection circuit board (50) and an inspected device (40), comprising:
(a) a plate-like housing (11) including a first surface opposed to a surface on which a terminal of the inspected device (40) is disposed and a second surface opposed to a surface on which an electrode of the inspection circuit board (50) is disposed, the housing (11) having a terminal-receiving holes (20) which extends through the housing (11) in the thickness direction thereof; and
(b) a connection terminal (30) attached to the housing (11) for electrically conducting the terminal of the inspected device (40) and the electrode of the inspection circuit board (50), the connection terminal (30) including a elastically deformable one-piece member which is a bent elongated member and being held in the terminal-receiving hole (20) in the housing (11) so as to be movable in the thickness direction of the housing (11).

2. The socket for an inspection apparatus (10) according to claim 1, wherein the terminal-receiving hole (20) includes an inspected-object-terminal-receiving portion (22) which is formed on the first main surface of the housing (11) for receiving the corresponding terminal of the inspected device (40).

3. The socket for an inspection apparatus (10) according to claim 2, wherein the terminal of the inspected device (40) is a solder ball (41), and the inspected-object-terminal-receiving portion (22) assumes the form of a cone whose diameter decreases toward a direction away from the first main surface of the housing (11).

4. The socket for an inspection apparatus (10) according to claim 3, wherein the inspected device (40) includes a plurality of solder bolls provided on the rear face thereof.

5. The socket for an inspection apparatus (10) according to claim 1, wherein the connection terminal (30) has a generally S-shape, and includes an inspected-object-side contact portion (31) which is located near the first main surface of the housing (11) and which comes into contact with the corresponding terminal of the inspected device (40), and an inspection-circuit-side contact portion (36) which is located on the second main surface of the housing (11) and which comes into contact with the corresponding electrode of the inspection circuit board (50).

6. The socket for an inspection apparatus (10) according to claim 1, wherein the connection terminal (30) is made of an elastically deformable member.

7. The socket for an inspection apparatus (10) according to claim 1, wherein the elastically deformable member is constituted by a one-piece member which is formed through bending of an elongated member.

8. The socket for an inspection apparatus (10) according to claim 1, wherein the terminal-receiving hole (20) includes a projecting wall (23) which projects in a direction perpendicular to the thickness direction of the housing (11); the connection terminal (30) includes a projecting portion (35) which projects in a direction opposite the projecting direction of the projecting wall (23); and the projecting portion (35) engages the projecting wall (23) to thereby prevent the connection terminal (30) from coming off the terminal-receiving hole (20).

9. The socket for an inspection apparatus (10) according to claim 1, wherein the housing 11 includes a plurality of terminal-receiving holes (20), each of the plurality of terminal-receiving holes(20) includes a projecting wall (23) which projects in a direction perpendicular to the thickness direction of the housing (11).

10. An inspection apparatus for inspecting an inspected device (40), comprising:
a circuit board (50) connecting to the inspection apparatus; and
a socket (10) for the inspection apparatus (10) mounted on said circuit board and mounting thereon the inspected device (40), said socket comprising:
(a) a plate-like housing (11) including a first surface opposed to a surface on which a terminal of the inspected device (40) is disposed and a second surface opposed to a surface on which an electrode of the inspection circuit board (50) is disposed, the housing (11) having a terminal-receiving holes (20) which extends through the housing (11) in the thickness direction thereof; and
(b) a connection terminal (30) attached to the housing (11) for electrically conducting the terminal of the inspected device (40) and the electrode of the inspection circuit board (50), the connection terminal (30) including an elastically deformable one-piece member which is a bent elongated member and being held in the terminal-receiving hole (20) in the housing (11) so as to be movable in the thickness direction of the housing (11).

11. The inspection apparatus according to claim 10, wherein said socket (10) is mounted directly on said circuit board (50), and said housing (11) of said socket (10) comprising mounting holes.

12. The inspection apparatus according to claim 10, wherein said socket (10) is mounted on said circuit board (50) via a mounting frame, and said housing (11) of said socket (10) is free of mounting holes.
